(19) United States
(12) Patent Application Publication
(10) Pub. No.: US 2022/0093401 A1
(43) Pub. Date: Mar. 24, 2022

(54) MANUFACTURING METHOD OF SILICON CARBIDE DEVICE AND SILICON CARBIDE

(71) Applicant: NuFlare Technology, Inc., Kanagawa (JP)

(72) Inventor: Kiyotaka Miyano, Tokyo (JP)

(21) Appl. No.: 17/539,579

(22) Filed: Dec. 1, 2021

Related U.S. Application Data
(63) Continuation of application No. 16/216,151, filed on Dec. 11, 2018.

(30) Foreign Application Priority Data
Dec. 15, 2017 (JP) 2017-240731

(51) Int. Cl. H01L 21/265; H01L 21/324; H01L 29/16; H01L 21/02

(52) U.S. Cl. CPC H01L 21/26506; H01L 21/324; H01L 21/02381; H01L 21/02612; H01L 21/02529; H01L 29/1608

(57) ABSTRACT

Provided is a method of manufacturing a semiconductor device according to an embodiment, including implanting carbon ions into a predetermined region of a silicon substrate; forming a silicon carbide layer on the silicon substrate by performing heat treatment on the silicon substrate implanted with the carbon ions; and removing at least a portion of the silicon substrate to expose the silicon carbide layer.

### CROSS-REFERENCE TO RELATED APPLICATION

This application is based upon and claims the benefit of priority from Japanese Patent Application No. 2017-240731, filed on Dec. 15, 2017, the entire contents of which are incorporated herein by reference.

### FIELD

Embodiments described herein relate generally to a method of manufacturing a semiconductor device.

### BACKGROUND

Silicon carbide (SiC) is a wide bandgap semiconductor. For this reason, SiC is excellent in transmittance with respect to light having a wide wavelength from ultraviolet rays to infrared rays. In addition, SiC has the advantage of being high in mechanical strength and thermal strength.

Up to now, it has been difficult to form a uniform and large-area SiC thin film without complicated processes such as forming a sintered body and polishing a surface of the sintered body smoothly.

### SUMMARY OF THE INVENTION

According to one aspect of the invention, there is provided a method of manufacturing a semiconductor device, including implanting carbon ions into a predetermined region of a silicon substrate; forming a silicon carbide layer on the silicon substrate by performing heat treatment on the silicon substrate implanted with the carbon ions; and removing at least a portion of the silicon substrate to expose the silicon carbide layer.

According to one aspect of the invention, there is provided a method of manufacturing a semiconductor device, including implanting oxygen ions into a predetermined region of a silicon substrate with a first projected range; implanting carbon ions into the predetermined region with a second projected range shallower than the first projected range; forming a silicon oxide layer in the silicon substrate by performing first heat treatment on the silicon substrate implanted with the oxygen ions; forming a silicon carbide layer in the silicon substrate by performing second heat treatment on the silicon substrate implanted with the carbon ions; and removing at least a portion of the silicon substrate to expose the silicon oxide layer and, after that, removing the silicon oxide layer to expose the silicon carbide layer.

### BRIEF DESCRIPTION OF THE DRAWINGS

FIGS. 1A to 1E are schematic cross-sectional diagrams of a method of manufacturing a semiconductor device according to an embodiment; and

FIG. 2 is a flowchart of the method of manufacturing a semiconductor device according to the embodiment.

### DETAILED DESCRIPTION OF THE EMBODIMENTS

Hereinafter, embodiments of the invention will be described with reference to the drawings.

### Embodiment

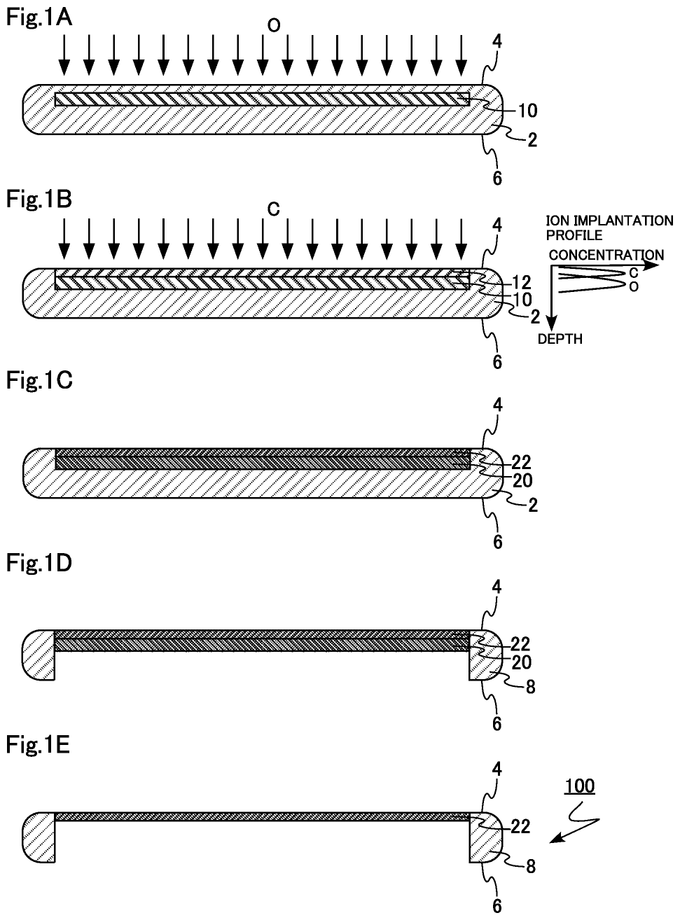

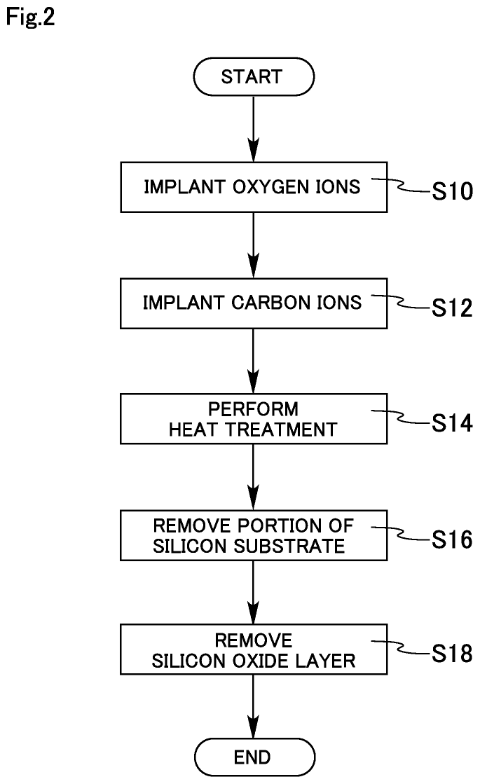

FIGS. 1A to 1E are schematic cross-sectional diagrams of a method of manufacturing a semiconductor device 100 according to the embodiment. FIG. 2 is a flowchart of the method of manufacturing a semiconductor device according to the embodiment.

First, oxygen (O) ion implantation is performed on a predetermined region of a surface 4 of a silicon substrate 2 with a predetermined projected range (hereinafter, referred to as an Rp) to form an oxygen ion implantation region 10 (FIG. 1A, S10 in FIG. 2).

The region where the ion implantation is performed can be determined by, for example, an opening of a mask formed using photoresist (not illustrated).

In addition, it is preferable that the projected range of oxygen ion implantation is 100 nm or more and 500 nm or less.

The Rp of oxygen ion implantation can be controlled by an acceleration voltage.

The plane orientation of the silicon substrate 2 may be any plane orientation such as {100} plane, {110} plane, or {111} plane.

The oxygen concentration in the depth direction in the ion implantation region can be more precisely controlled by performing the oxygen ion implantation in multiple times in a division manner while changing the Rp.

Next, carbon (C) ion implantation is performed on a predetermined region of the surface 4 of the silicon substrate 2 with a predetermined Rp to form a carbon ion implantation region 12 (FIG. 1B, S12 in FIG. 2).

The Rp of carbon ion implantation is, for example, 20 nm or more and 100 nm or less. It is preferable that the Rp of carbon ion implantation is shallower than the Rp of oxygen ion implantation.

It is preferable that the dose amount of carbon ion implantation is 1×10²² cm⁻³ or more.

The Pp of carbon ion implantation can be controlled by, for example, an acceleration voltage.

The carbon concentration in the depth direction in the ion implantation region can be more precisely controlled by performing the carbon ion implantation in multiple times in a division manner while changing the Rp or the like.

Next, heat treatment is performed (FIG. 1C, S14 in FIG. 2).

By the heat treatment, in the oxygen ion implantation region 10, the implanted oxygens react with the silicons in the silicon substrate 2 to form a silicon oxide layer 20. In addition, in the carbon ion implantation region 12, the implanted carbons react with silicons in the silicon substrate 2 to form a silicon carbide layer 22.

The thickness of the silicon oxide layer 20 is 100 nm or more and 500 nm or less.

In addition, the thickness of the silicon carbide layer 22 is 20 nm or more and 100 nm or less.

It is preferable that the heat treatment is performed in an atmosphere of an inert gas such as a nitrogen gas in order to form the high-quality silicon carbide layer 22. In addition, it is preferable that the temperature of the heat treatment is 800° C. or higher and 1200° C. or lower in order to form the high-quality silicon carbide layer 22. In addition, the silicon oxide layer 20 may be formed by the heat treatment before implanting carbon ions.

In addition, the silicon carbide layer 22 to be formed may be single-crystalline, amorphous or polycrystalline.

Next, at least a portion of the silicon substrate 2 is removed from a back surface 6 (FIG. 1D, S16 in FIG. 2). For example, a portion of the silicon substrate 2 is removed by etching with a fluoronitric acid (a mixed solution of a hydrofluoric acid and a nitric acid) from the back surface 6 side to expose the silicon oxide layer 20. A portion of the silicon substrate 2 which has not been removed by etching becomes a silicon substrate remaining portion 8 around the silicon oxide layer 20 and the silicon carbide layer 22.

Next, the silicon oxide layer 20 is removed by, for example, etching with a hydrofluoric acid or the like to expose the silicon carbide layer 22 (FIG. 1E, S18 in FIG. 2). As a result, the semiconductor device 100 according to the embodiment is obtained.

The semiconductor device 100 according to the embodiment includes a silicon carbide layer 22 which is a silicon carbide thin film having a thickness of 20 nm or more and 100 nm or less and the silicon substrate remaining portion 8 provided around the silicon carbide layer 22.

In addition, without performing oxygen ion implantation, by implanting only carbon ions and performing heat treatment, and after that, by etching the silicon substrate 2, the silicon carbide layer 22 may be exposed.

Next, the functions and effects of the method of manufacturing a semiconductor device according to the embodiment will be described.

By implanting carbon ions into the silicon substrate 2 and performing heat treatment, it is possible to easily form the large-area silicon carbide layer 22.

The silicon substrate 2 can be easily removed by etching. For this reason, it is possible to easily form a thin film of silicon carbide by the method of manufacturing a semiconductor device according to the embodiment.

In addition, before performing the carbon ion implantation, by implanting oxygen ions and performing heat treatment, the silicon oxide layer 20 is formed, so that the silicon oxide layer 20 can be formed under the silicon carbide layer 22.

The selection ratio between icon oxide and silicon is higher than the etching selection ratio between silicon carbide and silicon. For this reason, by providing the silicon oxide layer 20, the silicon oxide layer 20 functions as a stopper layer, and the silicon substrate 2 can be removed more easily.

In addition, it is preferable that etching with a hydrofluoric acid is used for removing the silicon oxide layer 20. Since silicon carbide is not easily eroded by the hydrofluoric acid, it is easy to selectively remove the silicon oxide layer 20 with respect to the silicon carbide layer 22.

In addition, it is preferable that the oxygen ion implantation is performed before the carbon ion implantation. When the oxygen ion implantation is performed after carbon ion implantation, carbons in the carbon ion implantation region 12 are recoiled (knocked on) by oxygens, and the carbons are distributed in a region closer to the back surface 6 than the original carbon ion implantation region. Furthermore, a region where carbons and oxygens are mixed is formed between the carbon ion implantation region 12 and the oxygen ion implantation region 10.

It is preferable that carbon atoms of which the number is equivalent to the number of Si atoms are supplied in forming the silicon carbide layer 22. For this reason, it is preferable that the dose amount of carbon ion implantation is 1×10²² cm⁻³ or more.

The semiconductor device obtained by the method of manufacturing a semiconductor device according to the embodiment can be preferably used for an optical lens, a high pressure discharge lamp bulb, a protective film for a lithography mask, various filters, and the like.

Heretofore, the embodiments of the invention have been described with reference to specific examples. The above-described embodiments are merely given as examples and do not limit the invention. Furthermore, the components of the embodiments may be appropriately combined.

While certain embodiments have been described, these embodiments have been presented by way of example only, and are not intended to limit the scope of the inventions. Indeed, the method of manufacturing a semiconductor device described herein may be embodied in a variety of other forms; furthermore, various omissions, substitutions and changes in the form of the devices and methods described herein may be made without departing front the spirit of the inventions. The accompanying claims and their equivalents are intended to cover such forms or modifications as would fall within the scope and spirit of the inventions.

1-18. (canceled)

19. A manufacturing method of a silicon carbide device, comprising:
implanting carbon ions into a predetermined region of a silicon substrate from a top of the silicon substrate to form a carbon ion implantation region exposed to an atmosphere at a top side of the silicon substrate, a projected range of the carbon ions being 20 nm or more and 100 nm or less;
performing heat treatment of the silicon substrate implanted with the carbon ions to form a silicon carbide layer being exposed to the atmosphere at the top side of the silicon substrate; and
removing at least a portion of the silicon substrate from a back of the silicon substrate to expose the silicon carbide layer.

20. The manufacturing method according to claim 19, wherein the heat treatment is performed at 800° C. or higher and 1200° C. or lower.

21. The manufacturing method according to claim 19, wherein the heat treatment is performed in an atmosphere of an inert gas.

22. The manufacturing method according to claim 19, wherein a dose amount of the carbon ion implantation is 1×10²² cm⁻³ or more.

23. A manufacturing method of a silicon carbide device, comprising:
implanting oxygen ions into a predetermined region of a silicon substrate with a first projected range;
implanting carbon ions into the predetermined region with a second projected range shallower than the first projected range;
forming a silicon oxide layer in the silicon substrate by performing first heat treatment on the silicon substrate implanted with the oxygen ions;
forming a silicon carbide layer in the silicon substrate by performing second heat treatment on the silicon substrate implanted with the carbon ions; and
removing at least a portion of the silicon substrate to expose the silicon oxide layer and, after that, removing the silicon oxide layer to expose the silicon carbide layer.

24. The manufacturing method according to claim 23, wherein the first projected range is 100 nm or more and 500 nm or less.

25. The manufacturing method according to claim 23, wherein the oxygen ions are implanted multiple times while changing the first projected range.

26. The manufacturing method according to claim 23, wherein the second projected range is 20 nm or more and 100 nm or less.

27. The manufacturing method according to claim 23, wherein the carbon ions are implanted multiple times while changing the second projected range.

28. The manufacturing method according to claim 23, wherein the first heat treatment and the second heat treatment are performed in an atmosphere of an inert gas.

29. The manufacturing method according to claim 23, wherein a temperature of the first heat treatment and the second heat treatment is 800° C. or higher and 1200° C. or lower.

30. The manufacturing method according to claim 23, wherein, after the oxygen ions are implanted, the carbon ions are implanted.

31. The manufacturing method according to claim 23, wherein the first heat treatment and the second heat treatment are included in a single heat treatment.

32. The manufacturing method according to claim 23, wherein a dose amount of the carbon ion implantation is 1×10²² cm⁻³ or more.

33. A silicon carbide device comprising:
a silicon carbide layer, manufactured by:
implanting carbon ions into a predetermined region of a silicon substrate from a top of the silicon substrate to form a carbon ion implantation region exposed to an atmosphere at a top side of the silicon substrate, a projected range of the carbon ions being 20 nm or more and 100 nm or less;
performing heat treatment of the silicon substrate implanted with the carbon ions to form a silicon carbide layer being exposed to the atmosphere at the top side of the silicon substrate; and
removing at least a portion of the silicon substrate from a back of the silicon substrate to expose the silicon carbide layer.

34. The silicon carbide device according to claim 33, wherein the silicon carbide layer is single-crystalline.

35. The silicon carbide device according to claim 33, wherein the silicon carbide layer is amorphous.

36. The silicon carbide device according to claim 33, wherein the silicon carbide layer is polycrystalline.

37. The silicon carbide device according to claim 33, wherein the silicon carbide layer is a silicon carbide thin film having a thickness of 20 nm or more and 100 nm or less.

38. The silicon carbide device according to claim 33, further comprising:
a silicon substrate remaining portion provided around the silicon carbide layer.
